(19) United States
(12) Patent Application Publication
(10) Pub. No.: US 2010/0045169 A1
(43) Pub. Date: Feb. 25, 2010

(54) NANO ELECTRONIC DEVICES

(75) Inventor: Youngtack SHIM, Seoul (KR)

Correspondence Address: KNOBBE MARTENS OLSON & BEAR LLP, 2040 MAIN STREET, FOURTEENTH FLOOR, IRVINE, CA, 92614, US

(73) Assignee: SEOUL NATIONAL UNIVERSITY RESEARCH & DEVELOPMENT BUSINESS FOUNDATION (SNU R&DB FOUNDATION), Seoul (KR)

(21) Appl. No.: 12/197,978

(22) Filed: Aug. 25, 2008

(51) Int. Cl. H01J 1/63; B32B 3/10; B05D 5/12; H01L 21/20; H01L 29/12; G03F 7/20

(52) U.S. Cl. 313/504; 427/58; 427/534; 428/109; 257/14; 430/324; 445/24; 438/478; 257/E29.071; 257/E21.09

(57) ABSTRACT

Nano material devices are provided. In one embodiment, a nano material device comprises a substrate, a first layer disposed on the substrate, a second layer and a third layer The first layer is configured to include a first set of electrodes at least partially parallel to each other and aligned in a first direction, and the third layer is configured to include a second set of electrodes at least partially parallel to each other and aligned in a third direction transverse to the first direction, thereby defining a plurality of intersections. The second layer is interposed between the first and third layers and configured to include an array of nano materials each element of which is configured to be disposed in each of the intersections.

### TECHNICAL FIELD

The present disclosure relates generally to nano technologies and more particularly, nano electronic devices.

### BACKGROUND

With the advent of nano technologies, various nano materials (e.g., nano particles) have become widely available in various industries. The ability to measure and manipulate materials on a nano-meter level is making it possible to recognize new nano materials with enhanced properties. In practice, nano particles are small particles that can range in size. Typically, nano particles can range from one nanometer to several hundred nanometers in diameter. The size of nano particles affords it unique mechanical, chemical, optical, transport and electrical properties. Nano particles have been found to be useful in many applications. Thus, nano particles are increasingly of great scientific interest as they can be an effective bridge between bulk materials and atomic or molecular structures.

With recent developments in nano technology, nano materials are being used to make various macro electronic devices, e.g., semiconductor-based devices. The size and properties of nano particles allow them to be used on a wide variety of products including, dyes and pigments; aesthetic or functional coatings; tools for biological discovery, medical imaging, and therapeutics; magnetic-recording media; quantum dots; and even uniform and nano-size semiconductors.

Typical electronic devices rely on conventional wiring technologies that use metal wiring lines or contain high impurity regions formed in a semiconductor substrate. Semiconductor-based devices have metal wiring layers that are formed on the semiconductor substrate and interconnect device elements formed on the surface of the semiconductor substrate. Further, portions of the semiconductor substrate that are doped with impurities may function as wiring lines within the elements formed on the surface of the semiconductor or between the elements.

Although the wiring lines are made fine and minute using modern photolithographic technologies, and thus, the semiconductor-based devices are made compact, the manufacturing processes of such wiring lines require forming film and manipulating techniques that are operable in high vacuum conditions, e.g., having pressure of 10⁻⁶˜10⁻³ mmHg. For example, metals such as aluminum and copper should be formed on the semiconductor substrate using physical vapor deposition techniques including sputtering and evaporation.

Relying on the above methods, however, it is not possible to efficiently make compact devices such as nano electronic devices. That is, despite superior mechanical, chemical or electrical properties of the nano materials, applications of such materials are limited, primarily due to a lack of suitable mechanisms for positioning such materials on a surface of a substrate or chip. Thus, it may be necessary to provide a method of aligning nano materials and providing an array of aligned nano materials to manufacture nano electronics devices.

### SUMMARY

Various embodiments of nano material technologies are disclosed herein. In one embodiment by way of non-limiting example, a device includes a substrate; a first layer disposed on the substrate and configured to include a first set of electrodes aligned in a first direction; a second layer disposed on the first layer and configured to include nano materials elongated in a second direction; and a third layer disposed on the second layer and configured to include a second set of electrodes aligned in a third direction.

The Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1A shows a perspective view of a device having nano materials in one embodiment;

FIG. 1B shows a detailed structure of the connection between a row of the first set of electrodes, elements of an array of nano materials and a column of the second set of electrodes in one embodiment;

FIG. 2 shows a perspective view of a substrate in one embodiment;

FIG. 3 shows a perspective view of a substrate and a first layer in one embodiment;

FIG. 4 shows a perspective view of a substrate and a patterned first layer in one embodiment;

FIG. 5 shows a perspective view of a first layer grooves in the first layer in one embodiment;

FIG. 6 shows a perspective view of a first set of electrodes disposed in the first layer grooves in one embodiment;

FIG. 7 shows a perspective view of a second layer disposed on the first layer in one embodiment;

FIG. 8 shows a perspective view of a second layer grooves formed in the second layer in one embodiment;

FIG. 9 shows a perspective view of the second layer having nano materials disposed in the second layer grooves in one embodiment;

FIG. 10 shows a perspective view of a third layer disposed on the second layer in one embodiment;

FIG. 11 shows a perspective view of a third layer patterned in a direction along its length in one embodiment;

FIG. 12 shows a perspective view of a third layer having trenches formed in the third layer in one embodiment;

FIG. 13 shows a perspective view of irradiating an ion beam onto the nano materials exposed through the trenches in one embodiment;

FIG. 14 illustrates an array of nano materials formed in the second layer in one embodiment;

FIG. 15 shows a perspective view of a third layer having an additional photoresist deposited on the patterned third layer of FIG. 12 in one embodiment;

FIG. 16 shows a perspective view of the third layer having a flat top surface thereof in one embodiment;

FIG. 17 shows a perspective view of a third layer patterned in a direction along its width in one embodiment;

FIG. 18 shows a perspective view of a third layer having a third layer groove in one embodiment;

FIG. 19 shows a perspective view of a second set of electrodes disposed in the third layer groove in one embodiment; and

FIG. 20 is a flow chart of an illustrative embodiment of a method for manufacturing a device having an array of nano materials.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made without departing from the spirit or scope of the subject matter presented here. It will be readily understood that the components of the present disclosure, as generally described herein, and illustrated in the Figures, may be arranged, substituted, combined, and designed in a wide variety of different configurations, all of which are explicitly contemplated and made part of this disclosure.

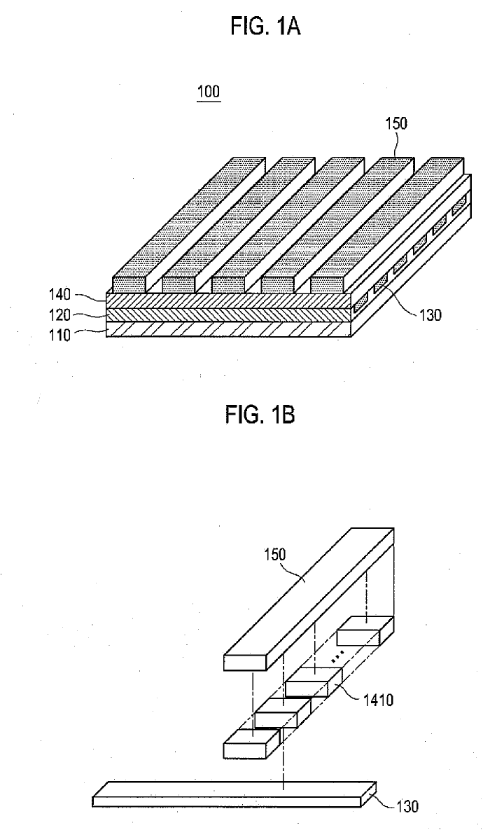

FIGS. 1A and 1B show a schematic view of an illustrative embodiment of a device 100 having an array of nano materials 1410, and the connection between a row of the first set of electrodes 130, elements of the array of nano materials 1410 and a column of the second set of electrodes 150. The device 100 includes a substrate 110, a first layer 120, a first set of electrodes 130, a second layer 140, and a second set of electrodes 150. The first layer 120 is disposed on the substrate 110 and incorporates the first set of electrodes 130 that extend in a first direction along a length of the first layer 20 thereon. The second layer 140 is deposited on the first layer 120 and includes the array of nano materials 1410 that maintain electric contact with the first set of electrodes 130. For example, the array of nano materials 1410 may be aligned to extend in a second direction of the substrate (e.g., along its width) that is substantially perpendicular to the first direction of the first set of electrodes 130. The second set of electrodes 150 is disposed on the second layer 140 in such a way that the second set of electrodes 150 are electrically in contact with one or more element of the array of nano materials 1410 in the second layer 140 In some embodiments, the second set of electrodes 150 may be aligned to extend in a direction that is the same as, or similar to the second direction in which the nano materials 910 extend (e.g., along its width).

Referring to FIG. 1B, a structural relation between one row of the first set of electrodes 130, elements of the array of nano materials 1410 and a column of the second set of electrodes 150 is illustrated. The first set of electrodes 130 is coupled to the second set of electrodes 150 through one element of the array of nano materials 1410. In one embodiment, the first set of electrodes 130 is at least in part coupled to at least one element of the array of nano materials 1410, and the second set of electrodes 150 is at least in part coupled to at least one element of the array of nano materials 1410. For example, an electrode from the first set of electrodes 130 is electrically connected to an electrode from the second set of electrodes 150 via a segment (i.e., an element) from the array of nano materials 1410. The array of nano materials 1410 may be configured to have an electrical contact with the first set of electrodes 150 at a lower side of the array of nano materials 1410, and to have an electrical contact with the second set of electrodes 150 at an upper side of the array of nano materials 140. In this way, each element in the array of nano materials 1410 in the second layer 140 may be activated one by one through selectively supplying an electric current to the selected pair among the rows of the first set of electrodes 130 (e.g., horizontal electrodes) and the columns of the second set of electrodes 150 (e.g., vertical electrodes). It is appreciated that although FIG. 1B shows the array of nano materials 1410 having one column of the elements, the array of nano materials 1410 may have M rows and N columns, wherein M and N are natural numbers that are equal to or greater than 1.

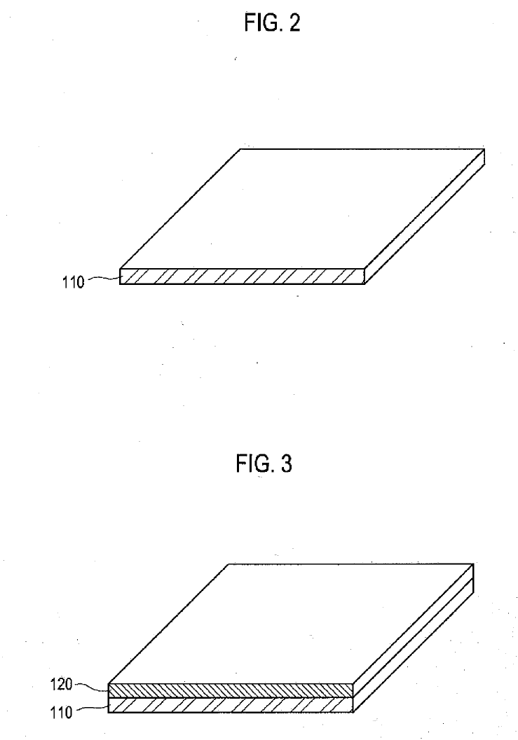

FIGS. 2 to 19 show exemplary stages in which the array of nano materials 1410 is fabricated. FIG. 2 illustrates a substrate 110 that is prepared in one embodiment. The substrate 110 may have a predetermined thickness depending on the scale of the device 100. The thickness of the substrate 110 may vary from tens of micrometers to hundreds of micrometers. Depending on the application field of the device 100, the substrate 110 may be made of silicon, glass, plastics (e.g., a polyethylene terephthalate), or the like. For instance, when the device 100 is used as a display or optical component (i.e., when it is desired to transmit light rays through the substrate 110), the substrate 110 may be made of and/or include transparent (or semi-transparent) materials including, but not limited to, indium tin oxide (ITO), indium zinc oxide (IZO) or its equivalents.

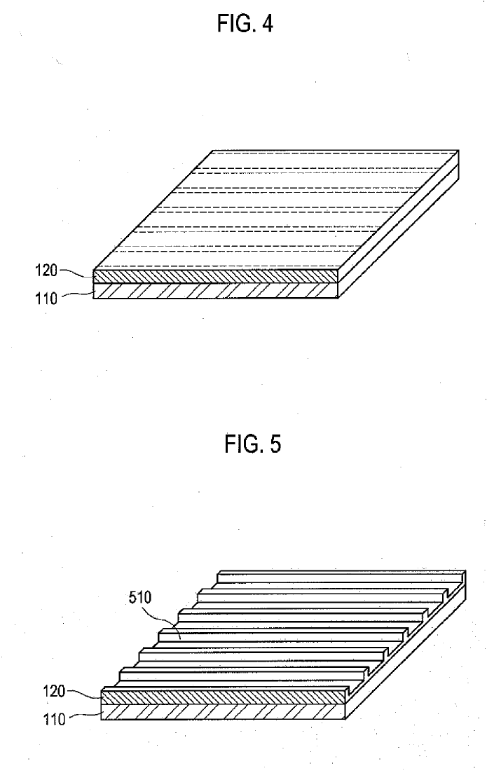

FIG. 3 shows a perspective view of a substrate 110 and a first layer 120 disposed on the substrate 110 in one embodiment. The first layer 120 may be made of or include photoresists that are deposited on the substrate 110. The photoresists may be of predetermined thickness. As shown in FIGS. 4 and 5, the first layer 120 is patterned to define first layer grooves 510 which extend along a length of the first layer 120 thereon. In one embodiment, the photoresists of the first layer 120 may be patterned or removed by various lithographic methods that are generally well known to those of ordinary skill in the semiconductor processing, MEMS processing, and nano technology fields. For example, a photolithography technique (or other equivalent method) may be used to pattern the photoresists of the first layer 120, thereby selectively removing parts of the photoresist in the first layer 120 to form the first layer grooves 510 as shown in FIG. 5. The photolithography technique uses light to transfer a geometric pattern from a photomask (not shown) to the photoresist of the first layer 120 on the substrate 110. For example, the photoresists of the first layer 120 may be used at wavelengths in the ultraviolet spectrum or shorter (e.g., <400 nm). As a result of the photolithography process, multiple first layer grooves 510 are formed on the first layer 120, as shown in FIG. 5. The first layer grooves 510 formed in the first layer 120 may be disposed in a uniform manner. Alternatively, the first layer grooves 510 may be disposed in varying directions.

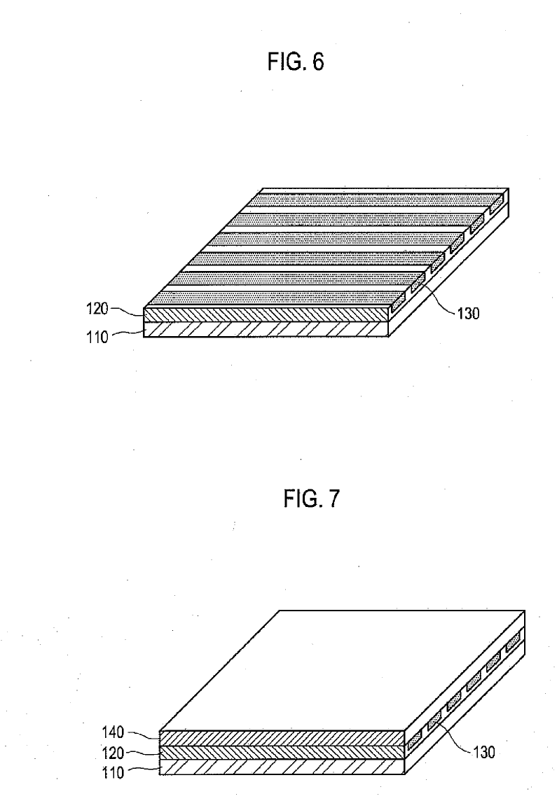

Referring to FIG. 6, a first set of electrodes 130 disposed in the first layer grooves 510 of the first layer 120 is illustrated. In one embodiment, a conductive material is deposited into the patterned first layer grooves 510 so as to form a first set of multiple electrodes 130. The first set of electrodes 130 may be made of or include any form of conductive material. Depending on the application field of the device 100, the electrodes 130 may be made of or include transparent or semi-transparent materials that allow light rays to be transmitted through the first set of electrodes 130. For example, the first set of electrodes 130 may be made of a transparent conductive material including, but not limited to, indium tin oxide (ITO) and indium zinc oxide (IZO). In another embodiment, the first set of electrodes 130 may be made of an opaque conductive material such as, e.g., magnesium, aluminum, indium, silver-magnesium or the like.

As shown in FIG. 7, a second layer 140 is disposed on the first layer 120 to thereby cover the first set of electrodes 130 in the first layer 120. In one embodiment, the second layer 140 may be made of or include photoresists that are deposited on the first layer 120. The photoresists may be of a predetermined thickness. Moreover, the photoresists of the second layer 140 may be the same as, similar to, or different from the materials used for the photoresists of the first layer 120. The photoresists of the second layer 140 may be used at wavelengths in the ultraviolet spectrum or shorter (e.g., <400 nm).

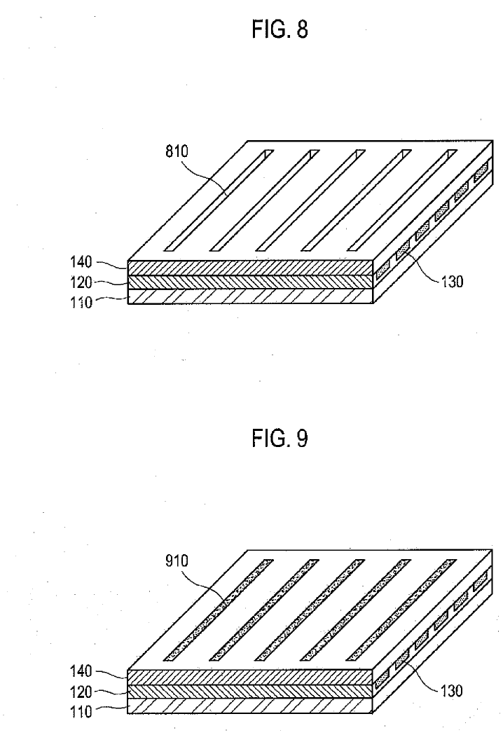

FIG. 8 shows a perspective view of a second layer grooves 810 formed in the second layer 140. In one embodiment, the second layer grooves 810 may extend along its width. Moreover, the photoresists may be patterned or removed by various lithographic methods that are generally well known to those of ordinary skill in the semiconductor processing, MEMS processing, and nano technology fields. For example, the photolithography technique may be used to form the second layer grooves 810 in the photoresists of the second layer 140. The photolithography removes the patterned portion of the second layer 140 until the second layer grooves 810 reaches the top surfaces of the first set of electrodes 130 disposed in the first layer 120. The second layer grooves 810 extend in a direction different from that of the first set of electrodes 130. In one embodiment, the second layer grooves 810 may elongate in a direction (e.g., along its width) perpendicular to the direction (e.g., along its length) of the first layer grooves 510.

FIG. 9 shows a perspective view of the second layer 140 having nano materials 910 disposed in the second layer grooves 810. In one embodiment, the nano materials 910 are absorbed, deposited or disposed into the second layer grooves 810. For example, a suspension or mixture of nano materials 910 is supplied on top of the photoresist of the second layer grooves 810. Such nano materials 910 may be formed to have shapes and sizes that match those of the second layer grooves 810. In this way, the nano materials 910 are captured into the second layer grooves 810. The nano materials 910 may define various shapes, examples of which may include, but are not limited to, elongated shapes such as nano-tubes and nano wire, round beads such as quantum dots, and the like. The nano materials 910 may also be made of or include carbon, silver, gold, and other prior art substances or compounds. The nano materials 910 may have aspect ratios that fall in the range of, e.g., greater than 20, greater than 50, greater than 100, greater than 1,000, greater than 10,000, or the like. In one embodiment, the second layer grooves 810 formed in the second layer 140 may be disposed in a uniform manner. Alternatively, the second layer grooves 810 may be disposed in varying directions.

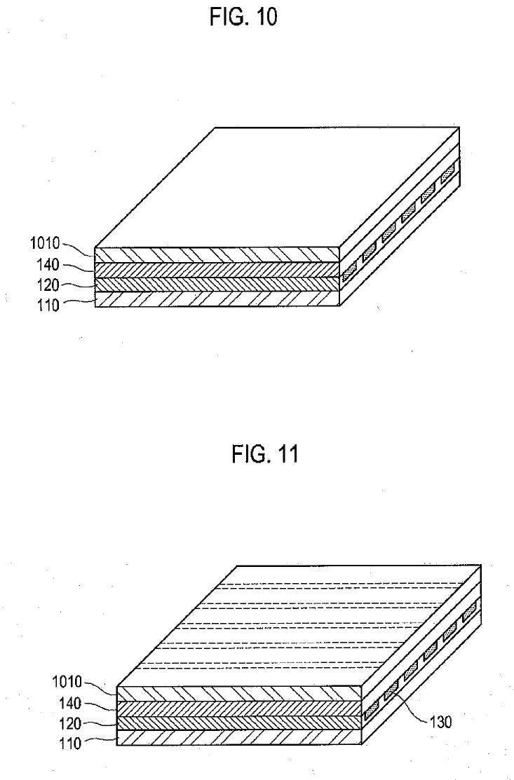

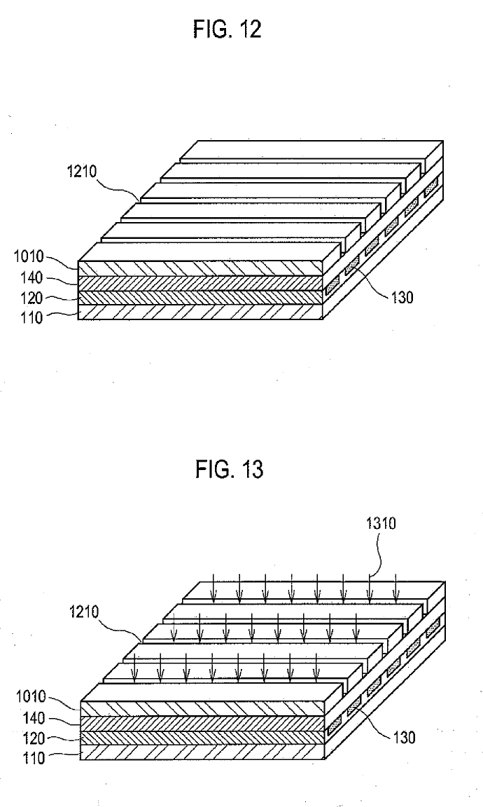

FIG. 10 shows a perspective view of a third layer 1010 disposed on the second layer 140. In one embodiment, the third layer 1010 may be made of or include photoresists that are deposited on the second layer 140, thereby trapping the nano materials 910 in the second layer grooves 810. The photoresists may be of a predetermined thickness. As shown in FIGS. 11 and 12, the photoresist of the third layer 1010 is patterned to define trenches 1210. In one embodiment, the trenches 1210 in a direction along its length over nano materials 910 elongated in a direction along its width. In some embodiments, a photolithography technique (or other equivalent method) may be used to pattern the photoresists of the third layer 1010 to selectively remove parts of the photoresist of the third layer 1010 to form the trenches 1210. The photolithography removes the patterned portion of the trenches 1210 until the trenches 1210 reaches the top surfaces of the nano materials 910 disposed in the second layer grooves 810. In this way, the photoresists of the third layer 1010 are patterned by using photolithography and the patterned photoresists are used as a mask to selectively expose the nano materials 910 on the second layer 140. The photoresists of the third layer 1010 may be the same as, similar to, or different the photoresists of the first layer 120. The photoresists of the third layer 1010 may be used at wavelengths in the ultraviolet spectrum or shorter (e.g., <400 nm). The trenches 1210 may be uniformly disposed. Alternatively, the third layer grooves 1110 may be disposed in varying directions. In one embodiment, the trenches 1210 may extend in parallel with the direction of the first layer grooves 510 (i.e., along the length of the first layer grooves 510). Alternatively, the trenches 1210 may extend in a direction different from the first layer grooves 510, e.g., a diagonal direction.

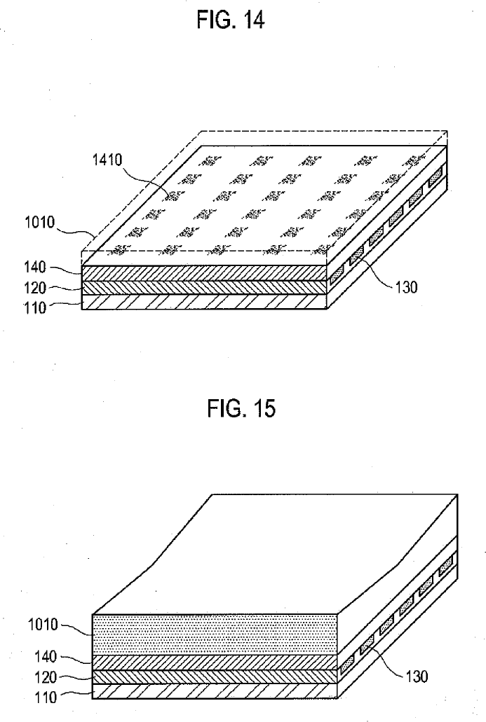

In one embodiment, exposed portions of the nano materials 910 may be removed from the device 100 through various means. For instance, FIG. 13 shows a perspective view of irradiating ion beams 1310 onto the nano materials 910 exposed through the trenches 1210 to remove the exposed portions of the nano materials 910. The ion beams 1310 are irradiated through the trenches 1210 such that the exposed portions of the nano materials 910 in the second layer 140 may be burnt or removed. The ion beams 1310 may be irradiated from a beam source (not shown) towards the surface of the third layer 1010. The ion beam source may include mercury vapor thrusters, duoplasmatron, and the like. The device 100 may be placed in a vacuum chamber and be exposed to the ion beam 1310, thereby abrading away the areas not covered by the photoresists. As a result, the nano materials 910 which originally had the elongated shapes (as shown in FIG. 9) are divided into multiple segments, thereby forming an array of nano materials 1410 as exemplified in FIG. 14. In this way, the array of nano materials 1410 may be formed so that the lower surface of the array of nano materials 1410 are in contact with the first set of electrodes 130 disposed in the first layer 120.

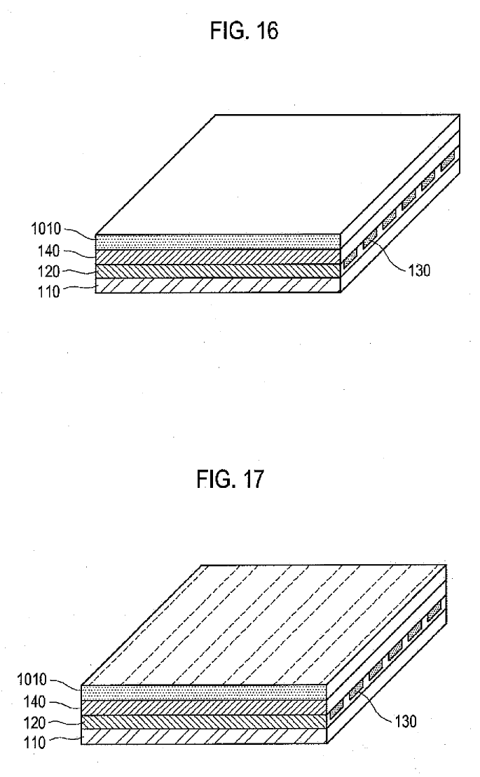

In another embodiment, FIG. 15 shows a perspective view of a third layer 1010 having an additional photoresist deposited on the trenches 1210. An additional layer of photoresist may be deposited on top of the previously-deposited and patterned third layer 1010 of FIG. 12 to cover the trenches 1210. The resulting uneven layer of photoresist of the third layer 1010 is processed to form a flat top surface, as shown in FIG. 16. The additional layer of the photoresist may be polished by using a metallography polish to create a flat, defect-free surface. Silicon based polishing pads or diamond solutions can also be used in the polishing process to facilitate the process.

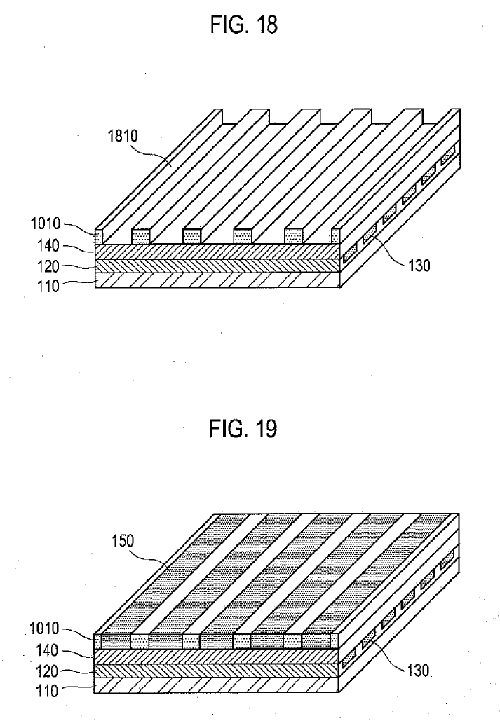

Referring to FIGS. 17 to 19, a perspective view of the additionally-deposited third layer 1010 having a second set of electrodes 150 extending in a direction different from that of the first set of electrodes 130 is shown. As shown in FIG. 17, the additionally-deposited third layer 1010 is patterned. In certain embodiments, the photoresists of the third layer 1010 are patterned by a lithography method to define multiple parallel third layer grooves 1810 extending in a direction along its width over the array of nano materials 1410. For example, a photolithography technique (or other equivalent method) may be used to pattern the third layer 1010 to selectively remove parts of the photoresist the third layer 1010. FIG. 18 shows multiple third layer grooves 1810 extending in a direction along its width that are formed in the third layer 1010 through photolithography. The photolithography is performed until each segmented nano material (i.e., each element of the array of nano material 1410) is exposed through the third layer grooves 180O. A conductive material is deposited into the patterned third layer grooves 1810 and forms a second set of multiple electrodes 150 as shown in FIG. 19. The second set of electrodes 150 are in contact with the array of nano materials 1410 disposed under the second set of electrodes 150. Similar to the first set of electrodes 130, the second set of electrodes 150 may be made of or include any conductive material. If some cases, the second set of electrodes 150 may be made of or include transparent or semi-transparent materials which allows light rays to be transmitted through the second set of electrodes 150. For example, the second set of electrodes 150 may be made of a transparent conductive material including, but not limited to, indium tin oxide (ITO), indium zinc oxide (IZO) and the like. Alternatively the second set of electrodes 150 may be made of an opaque conductive material including magnesium, aluminum, indium, silver-magnesium and the like. In this way, multiple sets of electrodes (i.e., the first and the second sets of electrodes 130 and 150) are located above and below the array of nano materials 1410 respectively, thereby making the device 100 into a so-called sandwich-type nano matrix device, as shown in FIG. 1.

In some embodiments, further photolithography may be performed exposing the second set of electrodes 150 and thereby forming them into particular patterns. For example, as shown in FIG. 1, the uppermost photoresist in the third layer 1010 may be removed to expose the second set of electrodes 150. The photoresist of the second layer 140 may also be removed (not included in the figures) thereby exposing the first set of electrodes 130.

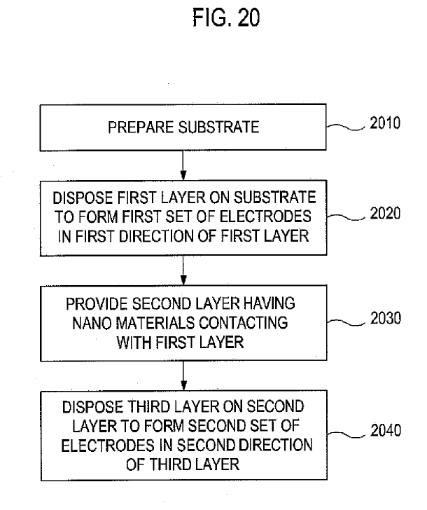

FIG. 20 is a flow chart of an illustrative embodiment of a method for manufacturing a device having an array of nano materials 1410. At block 2010, a substrate 110 is prepared. The substrate 110 may have a predetermined thickness. The thickness may be determined by the scale of the device 100. The thickness of the substrate 110 may vary from tens of micrometers to hundreds of micrometers Depending on the intended use of the device 100, the substrate 110 may be made of silicon, glass, plastic (e.g., a polyethylene terephthalate), and the like. For example, when the device 100 is used as a display or optical component (e.g., when it is desired to transmit light rays through the substrate 110), the substrate 110 may be made of and/or include transparent (or semi-transparent) materials including, but not limited to, indium tin oxide (ITO), indium zinc oxide (IZO) or its equivalents. Alternatively, the second set of electrodes 150 may be made of an opaque conductive material including but not limited to magnesium, aluminum, indium, silver-magnesium and the like.

At block 2020, a first layer 120 is disposed on the substrate 110 to form a first set of electrodes 130 in a first direction of the first layer 120 (e.g., along a length of the first layer 120 thereon). The first layer 120 may be made of or include photoresists that are deposited on the substrate 110. The photoresists may be of a predetermined thickness. The first layer 120 is patterned to define multiple parallel first layer grooves 510. The first layer grooves may extend in various directions including along the length of the first layer 120 thereon. In some embodiments, a photolithography technique (or other equivalent methods) may be used on the photoresists of the first layer 120 to selectively remove portions of the photoresists from the first layer 120 to form first layer grooves 510. The first layer grooves 510 formed may be disposed uniformly in a first direction (e.g., along the length of the first layer 20 thereon). Alternatively, the first layer grooves 510 may be disposed in varying directions. A conductive material is deposited into the patterned first layer grooves 510 so as to form a first set of multiple electrodes 130. The first set of electrodes 130 may be made of or include any number of conductive material. When desired, the electrodes 130 may be made of or include transparent or semi-transparent materials that allow the light rays to be transmitted through the electrodes 130. For example, the electrodes 130 may be made of a transparent conductive material including, but not limited to, indium tin oxide (ITO), indium zinc oxide (IZO) and the like. Alternatively, the first set of electrodes 130 may be made of an opaque conductive material including magnesium, aluminum, indium, silver-magnesium and the like.

At block 2030, a second layer 120 including nano materials 910 are in contact with the first set of electrodes 130 provided on the first layer 120. The second layer 140 may be made of or include photoresists that are deposited on the first layer 120, thereby covering the first set of electrodes 130. The photoresists may be of a predetermined thickness. The second layer 140 is patterned to define second layer grooves 810 which extend in a direction along its width. In some embodiments, the photoresists may be patterned or removed by various lithographic methods that are generally well known to those of ordinary skill in the semiconductor processing, MEMS processing, and nano technology fields. For example, a photolithography technique may be used to form the second layer grooves 810 in the photoresists of the second layer 140. The photolithography is continued until the second layer grooves 810 reach the top surfaces of the first set of electrodes 130. The second layer grooves 810 in the second layer 140 extend in a direction different from that of the first set of electrodes 130. For example, the second layer grooves 810 may elongate in a direction (e.g., along its width) perpendicular to the direction (e.g., along its length) of the first layer grooves 510. The nano materials 910 are then absorbed, deposited or disposed into the second layer grooves 810. In one embodiment, a suspension or mixture of nano materials 910 is supplied on top of the photoresist of the second layer grooves 810. Such nano materials 910 are elongated and have shapes and sizes that match those of the second layer grooves 811. In this way, the nano materials 910 are captured into the second layer grooves 810. The second layer grooves 810 formed in the second layer 140 may be disposed uniformly, e.g., in a direction along its width. Alternatively, the second layer grooves 810 may be disposed in varying directions.

At block 2040, a third layer 1010 is disposed on the second layer 140 to form a second set of electrodes 150 which are elongated in a second direction of the substrate 110 (e.g., along its width). The operation of disposing the third layer 1010 includes depositing photoresists to form an array of nano materials 1410 in the second layer 140 and depositing additional photoresists to form a second set of electrodes 150.

To form an array of nano materials 1410, the photoresist of the third layer 1010 is patterned, e.g., by photolithography to define multiple parallel trenches 1210 extending in a direction along its length over the nano materials 910 elongated in a direction along its width. The photolithography is continued until the trenches 1210 reach the top surface of the nano materials 910 disposed in the second layer groove 810 of the second layer 140. In this way, the photoresists of the third layer 1010 are patterned by using photolithography. The patterned photoresists are used as a mask to selectively expose the nano materials 910 on the second layer 140. The trenches 1210 may extend in parallel with the direction of the first layer grooves 510 (i.e., along its length), or in any other direction, e.g., a diagonal direction. In one embodiment, exposed portions of the nano materials 910 may be removed from the device 100 through various means. For example, ion beams 1310 are irradiated through the trenches 1210 such that the exposed portions of the nano materials 910 in the second layer 140 maybe burnt or removed. The ion beams 1310 may be irradiated from a beam source (not shown) towards the surface of the third layer 1010 The ion beam source may include mercury vapor thrusters, duoplasmatron, and the like. The device 100 may be placed in a vacuum chamber and be exposed to an ion beam 1310, thereby abrading away the areas not covered by the photoresists. As a result, the nano materials 910 which originally had the elongated shapes (as shown in FIG. 9) are divided into multiple segments in order to form an array of nano materials 1410. In this way, the array of nano materials 1410 may be formed so that the lower surface of each element of the array of the nano materials 1410 may be in contact with the first set of electrodes 130 disposed in the first layer 120.

To form the second set of electrodes 150 in the third layer 1010, an additional layer of the photoresist is deposited on top of the previously-deposited and patterned photoresist 1010 of FIG. 12 to bury the trenches 1210 in the third layer 1010. The additional layer of photoresist may be deposited on top of the previously-deposited and patterned third layer 1000 of FIG. 12 to cover the trenches 1210 The resulting uneven layer of the photoresist of the third layer 1010 is processed to form a flat top surface of the third layer 1010. For example, the third layer 1010 having additional layer of the photoresist may be polished by using a metallography polish to create a flat, defect-free surface of the third layer 1010. Silicon based polishing pads or diamond solution can be used in the polishing process to facilitate the process. A second set of electrodes 150 is provided in a direction different from that of the first set of electrodes 130. The third layer 1010 is patterned by lithography methods to define multiple parallel grooves extending along its width over the array of nano materials 1410. For example, a photolithography technique (or other equivalent methods) may be used on the third layer 1010 to selectively remove portions of the photoresist of the third layer 1010 thereby forming third layer grooves 1810 as shown in FIG. 18. The third layer grooves 1810 may extend in various directions, including along its width. The photolithography is performed until each of the segmented nano materials (i.e., each element of the array of nano materials 1410) are exposed through the third layer grooves 1810. A conductive material is deposited into the patterned third layer grooves 1810 forming a second set of multiple electrodes 150. The second set of electrodes 150 may be in contact with the array of nano materials 1410 disposed under the second set of electrodes 150. Similar to the first set of electrodes 130, the second set of electrodes 150 may be made of or include any conductive material and, when desirable, the second set of electrodes 150 may be made of or include transparent or semi-transparent materials that allow light rays to be transmitted through the second set of electrodes 150. For example, the second set of electrodes 150 may be made of a transparent conductive material including, but not limited to, indium tin oxide (ITO) and indium zinc oxide (IZO). Alternatively, the second set of electrodes 150 may be made of an opaque conductive material including magnesium, aluminum, indium, silver-magnesium and the like. In this way, multiple sets of electrodes (i.e., the first and the second sets of electrodes 130 and 150) are provided over and below the array of nano materials 1410 respectively, thereby making the device 100 into a so-called sandwich-type or array-type nano matrix device as illustrated in FIG. 1.

With the array of nano materials 1410 of FIG. 1, one can selectively supply electric current or apply electric voltage to each of the first set of electrodes and each of the second set of electrodes, thereby manipulating each element of the array of nano materials 1410. Accordingly, the array of nano materials 1410 can be used for various purposes. In one example, the array of nano materials 1410 may be used for a switch box in which a user can open and close each element of the array of nano materials 1410 by selectively supplying the electric current or applying voltage through desired first and second electrodes 130 and 150. In another example, the array of nano materials 1410 may be used for a memory device in which a user can activate and deactivate each element of the array of nano materials 1410 by selectively supplying the electric current or voltage through desired first and second electrodes 130 and 150. In another example, the array of nano materials 1410 may be used for a light emitting device in which each element of the array of nano materials 1410 may emit light of desired wavelengths when selectively supplied with the electric current or voltage through desired first and second electrodes. It is appreciated that nano materials used to make the array of nano materials 1410 have suitable physical, chemical, electrical, and/or optical properties when they are used as the switch box, memory device, and/or light emitting device, where such desired properties are well known to those skilled in the relevant art.

It is appreciated that the above process for fabricating the nano matrix device may be performed using various substrates and photoresists as long as such materials can conform to the above process. Nano materials 910 with aspect ratios that fall in the range of, e.g., greater than 20, greater than 50, greater than 100, greater than 1,000, greater than 10,000, or the like may be used. In addition, the photoresists and/or substrate may be patterned or removed by various conventional lithographic methods. In general, selection of the above materials and lithographic methods are generally well known to those of ordinary skill in the semiconductor processing, MEMS processing, and nano technology.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the disclosed embodiments.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A device comprising:
a substrate;
a first layer disposed on the substrate and configured to include a first set of electrodes at least partially parallel to each other and aligned in a first direction;
a third layer disposed on the first layer and configured to include a second set of electrodes at least partially parallel to each other and aligned in a third direction transverse to the first direction, thereby defining a plurality of intersections; and
a second layer interposed between the first and third layers and configured to include a plurality of nano materials each element of which is configured to be disposed in each of the intersections.

2. The device of claim 1, wherein the nano materials form an array of nano materials.

3. The device of claim 1, wherein the third direction is substantially perpendicular to the first direction.

4. The device of claim 2, wherein the first set of electrodes is electrically coupled to the second set of electrodes via the array of nano materials.

5. The device of claim 2, wherein the array of nano materials are configured to have an electrical contact with the first set of electrodes at a lower side of the array of nano materials.

6. The device of claim 2, wherein the array of nano materials are configured to have an electrical contact with the second set of electrodes at an upper side of the array of nano materials.

7. The device of claim 2, wherein the array of nano materials are arranged in an M-by-N matrix.

8. The device of claim 2, wherein the electrode from the first set of electrodes is coupled to the electrode from the second set of electrodes via a segment from the array of nano materials.

9. The device of claim 2, wherein the array of nano materials is made of nano materials including at least one of nano tubes, nano wires, and quantum dots.

10. The device of claim 1, wherein the first layer is made of a transparent conductive material.

11. The device of claim 10, wherein the transparent conductive material includes indium tin oxide (ITO)

12. The device of claim 11, wherein the transparent conductive material includes indium zinc oxide (IZO).

13. The device of claim 1, wherein the nano materials have aspect ratios greater than or equal to 20.

14. The device of claim 1, wherein the first set of electrodes is made of a transparent conductive material.

15. The device of claim 14, wherein the transparent conductive material includes indium tin oxide (ITO).

16. The device of claim 14, wherein the transparent conductive material includes indium zinc oxide (IZO).

17. The device of claim 1, wherein the first set of electrodes is made of an opaque conductive material.

18. The device of claim 17, wherein the opaque conductive material includes materials selected from the group consisting of magnesium, aluminum, indium, and silver-magnesium.

19. The device of claim 1, wherein each row of the first set of electrodes is disposed in a uniform manner.

20. The device of claim 1, wherein the device is one of a switch, a memory, and a display.

21. A device comprising:
a substrate;
a first layer disposed on the substrate and configured to include a first set of electrodes aligned in a direction;
a second layer disposed on the first layer and configured to include an array of nano materials; and
a third layer disposed on the second layer and configured to include a second set of electrodes aligned in a second direction, wherein an electrode from the first set of electrodes is coupled to an electrode from the second set of electrodes via a segment from the array of nano materials.

22. A method comprising:
preparing a substrate;
disposing a first layer on the substrate, wherein the first layer includes a first set of electrodes aligned in a first direction;
providing a second layer on the first layer, wherein the second layer includes a plurality of second layer grooves configured to receive a plurality of nano materials;
disposing a third layer on the second layer, wherein the third layer includes a second set of electrodes aligned in a third direction; and
removing portions of the second layer and the plurality of nano materials, thereby forming an array of nano materials each interposed between the first and second electrodes in each intersection of the first and second electrodes.

23. The method of claim 22, wherein the third direction is substantially perpendicular to the first direction.

24. The method of claim 22, wherein disposing the first layer further comprising depositing a photoresist on the substrate.

25. The method of claim 24, wherein disposing the first layer further comprising patterning the photoresist to define a first layer groove which extends in the first direction.

26. The method of claim 25, wherein disposing the first layer further comprising depositing a conductive material in the first layer groove, thereby forming the first set of electrodes.

27. The method of claim 24, wherein the photoresist is patterned by using photolithography.

28. The method of claim 22, wherein providing the second layer further comprising depositing a photoresist on the first layer.

29. The method of claim 28, wherein providing the second layer further comprising patterning the photoresist to define the plurality of second layer grooves which extends in the second direction.

30. The method of claim 29, wherein providing the second layer further comprising disposing the plurality of nano materials in the plurality of second layer grooves.

31. The method of claim 22, wherein disposing the third layer further comprising depositing a photoresist on the second layer.

32. The method of claim 31, wherein disposing the third layer further comprising patterning the photoresist to define a trench which extends in the first direction.

33. The method of claim 32, wherein disposing the third layer further comprising irradiating ion beams to remove the plurality of nano materials exposed through the trench.

34. The method of claim 33, wherein disposing the third layer further comprising depositing an additional photoresist on the trench and processing the additional photoresist to form a flat top surface thereof.

35. The method of claim 34, wherein disposing the third layer includes patterning the additional photoresist to define a third layer groove.

36. The method of claim 35, wherein disposing the third layer further comprising depositing a conductive material in the third layer groove, thereby forming the second set of electrodes.

37. The method of claim 32, wherein the photoresist is patterned by using photolithography.

38. The method of claim 22 further comprising supplying electric current through a desired row of the first set of electrodes, a desired element of the array of the nano materials, and a desired column of the second set of electrodes, thereby using the array of nano materials as a switch.

39. The method of claim 22 further comprising supplying electric voltage through a desired row of the first set of electrodes, a desired element of the array of the nano materials, and a desired column of the second set of electrode, thereby using the array of nano materials as a memory.

40. The method of claim 22 further comprising:
arranging the plurality of nano materials to emit light rays of desired wavelengths when electric current flows therein; and
supplying the electric current through a desired row of the first set of electrodes, a desired element of the array of the nano materials, and a desired column of the second set of electrodes, thereby using the array of nano materials as a display.

41. A method comprising:
preparing a substrate;
disposing a first layer on the substrate, wherein the first layer includes a first set of electrodes aligned in a first direction;
providing a second layer on the first layer, wherein the second layer includes a plurality of second layer grooves, wherein the second layer grooves are configured to receive a plurality of nano materials; and
disposing a third layer on the second layer, wherein the third layer includes a second set of electrodes aligned in a second direction wherein an electrode from the first set of electrodes is coupled to an electrode from the second set of electrodes via a segment from the plurality of nano materials.
